(19) United States
(12) Patent Application Publication
(10) Pub. No.: US 2026/0239921 A1
(43) Pub. Date: Aug. 13, 2026

(54) APPARATUS AND METHODS FOR SUBSTRATE-TO-SUBSTRATE BONDING

(71) Applicant: Applied Materials, Inc., Santa Clara, CA (US)

(72) Inventor: Vijay D. PARKHE, San Jose, CA (US)

(21) Appl. No.: 19/050,229

(22) Filed: Feb. 11, 2025

(51) Int. Cl. H01L 21/683; H01L 23/00

(52) U.S. Cl. CPC H10P 72/722; H10W 72/071

(57) ABSTRACT

A chuck for a substrate includes a plurality of chucking units. Each chucking unit includes a chuck element having a substrate support surface and a chucking electrode. Each chuck element receives a portion of a substrate on the substrate support surface. Each chuck element is coupled to a base of the chuck by a driver having first and second actuators. Actuation of the drivers facilitates deforming the substrate, such as in preparation for a bonding operation.

### BACKGROUND

### Field

Embodiments of the present disclosure generally relate to systems, apparatus, and methods for wafer/substrate bonding. More specifically, embodiments of the present disclosure relate to methods and apparatus for substrate-to-substrate bonding.

### Description of the Related Art

Substrate-to-substrate bonding is a technique utilized in semiconductor device manufacturing in which two substrates are joined together as a single composite structure. To form the single composite structure, the substrates are first precisely aligned and then bonded together by fusion, thermal compression, or an adhesive. Each of the mechanisms for bonding the substrates/wafers together has disadvantages.

For example, avoiding outgassing is difficult when using adhesives and the strength of the adhesive bond often degrades over time. Thermal compression can cause stresses, warping, and other damage to the substrates/wafers during the bonding process. Fusion requires the surfaces of the substrates/wafers to be clean, smooth, and flat in order to bond the surfaces without voids or weak spots and a high-temperature annealing process to strengthen the bond. Accordingly, bonding the substrates/wafers via fusion involves integration of planarization, cleaning, and alignment processes to prepare the substrates/wafers for mechanical and thermal processes to bond the prepared substrates/wafers. The number of processes needed for fusion bonding often results in quality/uniformity variations in the bonds of wafer/substrate pairs.

Accordingly, there is a need in the art for a substrate-to-substrate bonding system and process that solves the problems described above.

### SUMMARY

The present disclosure generally relates to systems, apparatus, and methods for bonding substrates (also referred to as wafers), and particularly for substrate-to-substrate bonding. In one aspect, an apparatus for chucking a substrate includes a chuck element including a chucking electrode and a substrate support surface. A first actuator is coupled to the chuck element, and is configured to move the chuck element in first increments of distance. A second actuator is coupled to the chuck element, and is configured to move the chuck element in second increments of distance. The second increments are different from the first increments.

In another aspect, a chuck for a substrate includes a base and a plurality of chucking units that are coupled to the base. Each chucking unit includes a chuck element including a chucking electrode and a substrate support surface. Each chucking unit further includes a driver coupling the chuck element to the base. The driver includes a first actuator configured to move the chuck element relative to the base in first increments of distance. The driver further includes a second actuator configured to move the chuck element relative to the base in second increments of distance. The second increments are different from the first increments.

In another aspect, a method of manipulating a substrate includes securing a substrate to a chuck by applying a first voltage to a first chucking electrode of a first chuck element, and applying a second voltage to a second chucking electrode of a second chuck element. The method further includes deforming the substrate using the chuck. Deforming the substrate using the chuck includes causing a first actuator of a first driver coupled to the first chuck element to move the first chuck element and a first portion of the substrate. Deforming the substrate using the chuck further includes causing a second actuator of the first driver to move the first chuck element and the first portion of the substrate.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of the scope of the disclosure, as the disclosure may admit to other equally effective embodiments.

FIGS. 1A to 1D schematically illustrate a substrate bonding process being conducted using a bonding system.

FIGS. 2A and 2B schematically illustrate a chuck that may be used in the substrate bonding process depicted in FIGS. 1A to 1D.

FIGS. 3A to 3C schematically illustrate embodiments of a component of the chuck of FIGS. 2A and 2B.

FIG. 4A schematically illustrates an example of the component depicted in FIG. 3A in further detail.

FIGS. 4B and 4C schematically illustrate the component depicted in FIG. 4A at different stages of actuation.

FIGS. 5A to 5F schematically illustrate substrate bonding operations using components depicted in FIG. 3C.

FIG. 6 is a flowchart of a method of manipulating a substrate.

To facilitate understanding, identical reference numerals have been used, where possible, to designate identical elements that are common to the figures. One or more elements or features of any one embodiment or example may be beneficially incorporated in any one or more other non-mutually exclusive embodiments or examples.

### DETAILED DESCRIPTION

The present disclosure concerns systems, apparatus, and methods for bonding substrates (also referred to as wafers), and particularly relates to substrate-to-substrate bonding. Moreover, embodiments of the present disclosure relate to configurations of chucks, such as electrostatic chucks, that can be used in substrate-to-substrate bonding. In some embodiments, a first substrate includes first chiplets that become bonded to corresponding second chiplets of a second substrate. At least one substrate can be deformed to enable precise control of an initial contact location and extent between the substrate and the other substrate. The systems, apparatus, and methods of the present disclosure further enable precise control of the progression of substrate-to-substrate contact during the bonding process.

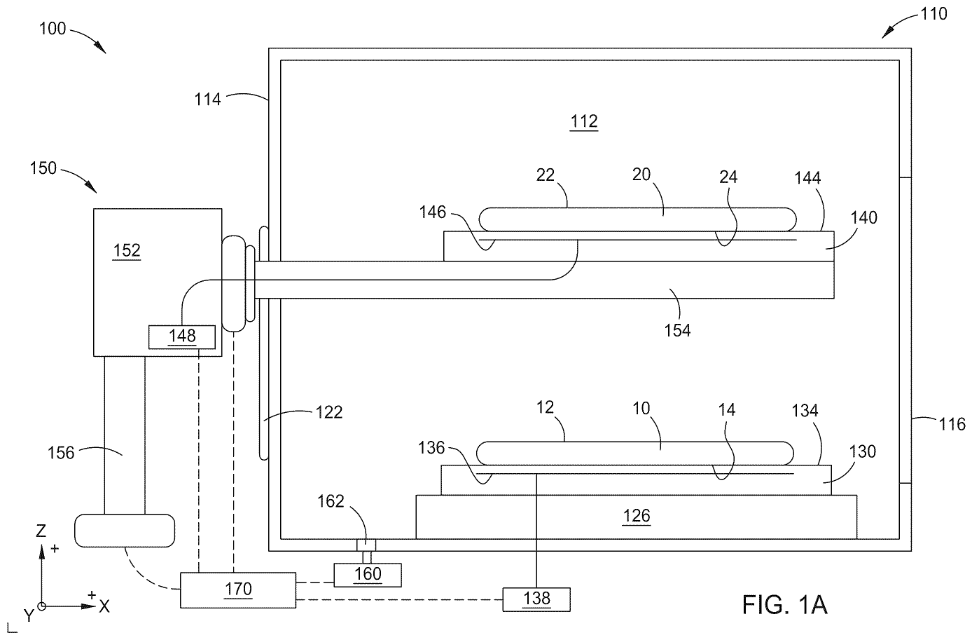

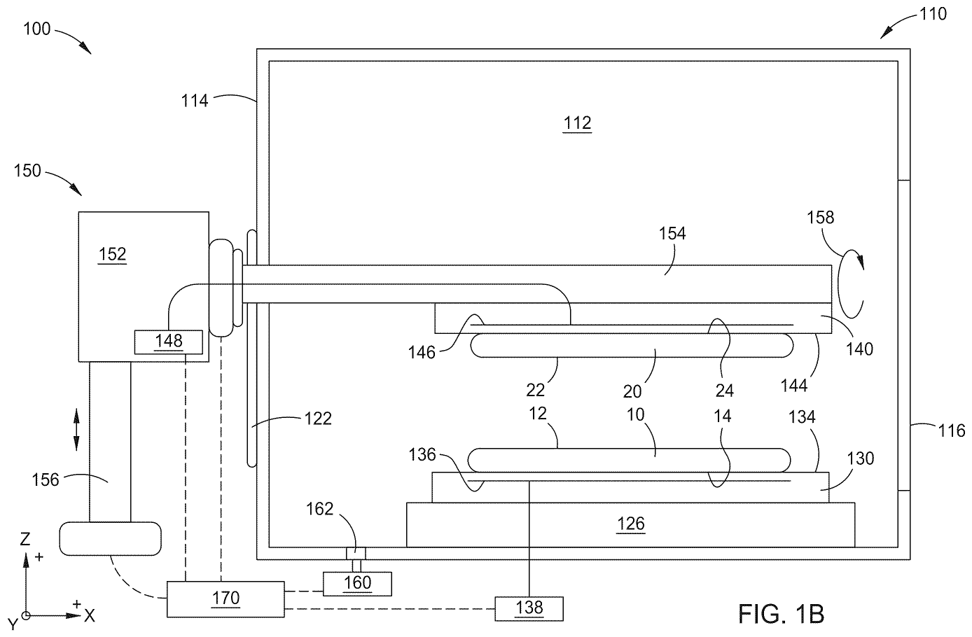

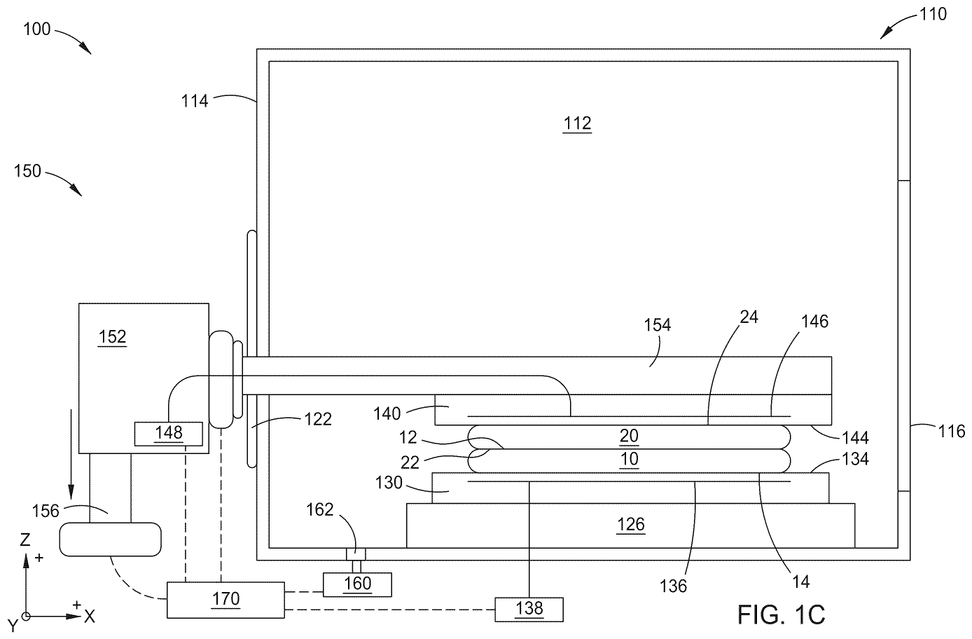

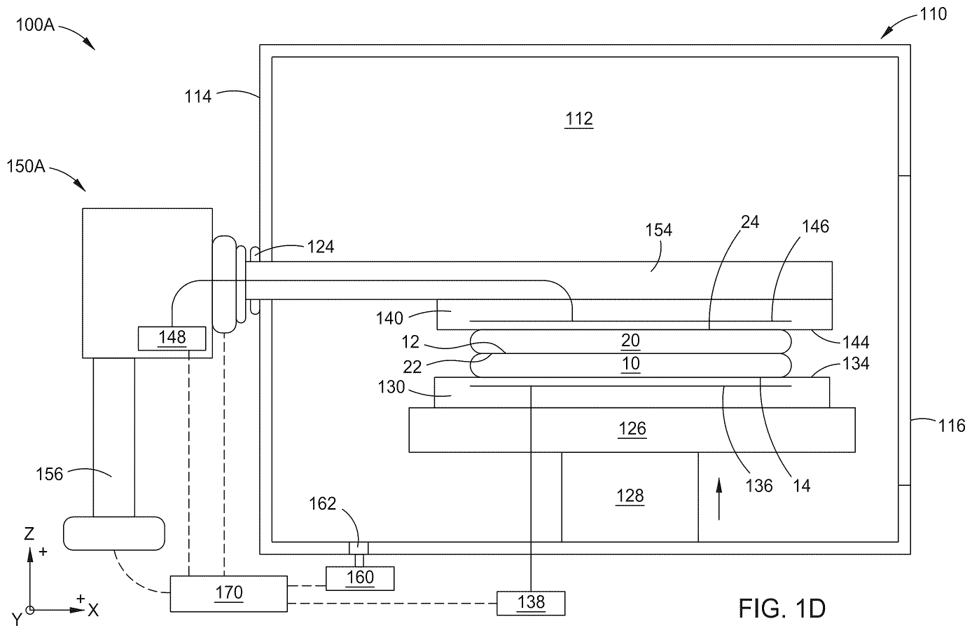

FIGS. 1A to 1D schematically illustrate a substrate bonding process being conducted using a bonding system 100. As shown schematically in FIG. 1A, the bonding system 100 includes a processing chamber 110 and a rotation system 150.

The rotation system 150 includes a motor 152 that rotates a rotation arm 154 about an axis in the X direction. In some examples, the motor 152 is a stepper motor. In some embodiments that may be combined with other embodiments, the motor 152 and rotation arm 154 are raised and lowered in the Z direction by an actuator 156. In some examples that may be combined with other examples, the actuator 156 includes a motor, such as a stepper motor, that rotates a lead screw. In some examples that may be combined with other examples, the actuator 156 includes a piston.

As illustrated, in some embodiments that may be combined with other embodiments, the motor 152 and actuator 156 are located outside the processing chamber 110, and the rotation arm 154 extends through a sidewall 114 of the processing chamber 110 into a processing volume 112 of the processing chamber 110. In some embodiments that may be combined with other embodiments, the motor 152 and the rotation arm 154 are disposed in the processing chamber 110, and the actuator 156 is located outside the processing chamber 110. In some examples, the actuator 156 may be coupled to the motor 152 by a bracket that extends through the sidewall 114 of the processing chamber 110. In some embodiments that may be combined with other embodiments, the motor 152, the rotation arm 154, and the actuator 156 are disposed in the processing chamber 110.

As illustrated, in embodiments in which at least one of the motor 152 or the actuator 156 are located outside the processing chamber 110, a seal assembly 122 at the sidewall 114 maintains a pressure isolation of the processing volume 112 of the processing chamber 110. In some examples, the seal assembly 122 includes a bellows or a boot, such as an elastomeric boot. The seal assembly 122 is configured to permit vertical movement of the motor 152 and the rotation arm 154 in the Z direction while maintaining a controlled pressure environment within the processing volume 112. In some embodiments in which the motor 152, the rotation arm 154, and the actuator 156 are disposed in the processing chamber 110, the seal assembly 122 may be omitted.

In some embodiments that may be combined with other embodiments, an atmosphere control system 160 is fluidically coupled to the processing chamber 110 at one or more ports 162. In some embodiments that may be combined with other embodiments, the atmosphere control system 160 includes one or more gas sources configured to provide one or more gases into the processing chamber 110. Exemplary gases include purge gases, or cleaning gases. In some embodiments that may be combined with other embodiments, the atmosphere control system 160 includes, or is coupled to, a vacuum system in order to adjust a pressure inside at least a portion of the processing chamber 110. In some embodiments that may be combined with other embodiments, the substrate bonding process using the bonding system 100 is conducted in an enclosed environment at pressures less than atmospheric pressure (i.e., vacuum pressures (<760 Torr)). In some embodiments that may be combined with other embodiments, the atmosphere control system 160 and/or the one or more ports 162 may be omitted.

A first chuck 130 is disposed on a stage 126 in the processing volume 112. The first chuck 130 includes one or more chucking electrodes 136 coupled to a first voltage source 138. A first substrate 10 is chucked to a support surface 134 of the first chuck 130 by the application of a voltage by the first voltage source 138 to the one or more chucking electrodes 136. A second chuck 140 is coupled to the rotation arm 154 in the processing volume 112. The second chuck 140 includes one or more chucking electrodes 146 coupled to a second voltage source 148. In some embodiments that may be combined with other embodiments, the one or more chucking electrodes 146 are coupled to the first voltage source 138, and the second voltage source 148 is omitted. A second substrate 20 is chucked to a support surface 144 of the second chuck 140 by the application of a voltage by the second voltage source 148 to the one or more chucking electrodes 146. The first substrate 10 and the second substrate 20 are conveyed into and out of the processing chamber 110 through an access port 116 that can be sealed in order to maintain a controlled pressure environment within the processing volume 112.

As shown schematically in FIG. 1A, the bottom side 14 of the first substrate 10 interfaces with the support surface 134 of the first chuck 130 while the top side 12 of the first substrate 10 is oriented in a first direction within the processing volume 112. The first direction is facing in the positive Z direction towards the rotation arm 154 of the rotation system 150 with respect to a location of the first substrate 10 within the processing volume 112. The bottom side 24 of the second substrate 20 interfaces with the support surface 144 of the second chuck 140 and the top side 22 of the second substrate 20 is oriented in the first direction within the processing volume 112. The top side 22 of the second substrate 20 is configured to be bonded to the top side 12 of the first substrate 10. For example, the top sides 12, 22 have been prepared, oriented in the XY plane, and aligned in the Z direction for bonding.

In some embodiments that may be combined with other embodiments, operation of the bonding system 100 is controlled by a controller 170. In some embodiments that may be combined with other embodiments, the controller 170 manages the bonding process. The controller 170 includes a central processing unit (CPU), a memory containing instructions, and support circuits for the CPU. The memory, or non-transitory computer readable medium, is one or more of a readily available memory such as random access memory (RAM), read only memory (ROM), floppy disk, hard disk, flash drive, or any other form of digital storage, local or remote. The support circuits are coupled to the CPU for supporting the CPU. The support circuits include cache, power supplies, clock circuits, input/output circuitry and subsystems, and the like. Operations and operating parameters are stored in the memory as a software routine that is executed or invoked to configure the controller 170 into a specific purpose controller to control the operations of the bonding system 100. The controller 170 is configured to conduct one or more of the operations described herein. The instructions stored on the memory, when executed, cause one or more of the operations described herein to be conducted.

In some embodiments that may be combined with other embodiments, the controller 170 manages the operation of the processing chamber 110, such as by controlling a temperature, a pressure, or an atmospheric composition of the processing volume 112. In some embodiments that may be combined with other embodiments, the controller 170 manages the operation of the atmosphere control system 160. In some embodiments that may be combined with other embodiments, the controller 170 manages the operation of the first voltage source 138 and the second voltage source 148. In some embodiments that may be combined with other embodiments, the controller 170 manages the operation of the rotation system 150. In some embodiments that may be combined with other embodiments, the controller 170 manages the operation of the first chuck 130 and the second chuck 140. In some embodiments that may be combined with other embodiments, the controller 170 manages substrate transfer operations.

In some embodiments that may be combined with other embodiments, the controller 170 includes, or is coupled to, a transmitter/receiver that facilitates communication with other devices, such as a base station or other controllers of other processing chambers or other systems.

FIG. 1B schematically illustrates the second chuck 140 with the second substrate 20 having been rotated about an axis in the X direction within the processing volume 112. In some embodiments that may be combined with other embodiments, the controller 170 controls the rotation system 150 to rotate the rotation arm 154 in a rotational direction 328 (such as by 180 degrees) within the processing volume 112. After the rotation of the rotation arm 154 in the rotational direction 328 within the processing volume 112, the top side 22 of the second substrate 20 is oriented in a second direction that is opposite to the first direction. In other words, the top side 22 of the second substrate 20 and the top side 12 of the first substrate 10 are facing each other. In some examples, the top side 22 of the second substrate 20 is positioned by the rotation arm 154 to be parallel to the top side 12 of the first substrate 10. Accordingly, after the top sides 12, 22 are oriented to face each other, the top sides 12, 22 of the first and second substrates 10, 20, respectively, can be bonded together to form a single composite structure.

FIG. 1C schematically illustrates the second chuck 140 with the second substrate 20 having been moved in the Z direction towards the first substrate 10. In some embodiments, the controller 170 controls the actuator 156 to move the motor 152 and rotation arm 154 in the negative Z direction to move the second chuck 140 and the second substrate 20 towards the first substrate 10 within the processing volume 112. In some examples, the actuator 156 moves the motor 152 and rotation arm 154 until the top side 22 of the second substrate 20 contacts the top side 12 of the first substrate 10.

However, in other examples, the actuator 156 moves the motor 152 and rotation arm 154 until the top side 22 of the second substrate 20 is separated from the top side 12 of the first substrate 10 by a relatively small distance, such as 25 mm or less, 20 mm or less, 15 mm or less, 10 mm or less, or 5 mm or less. In at least some of such examples, one or more components of the first chuck 130 and/or one or more components of the second chuck 140 are actuated to bring the top side 22 of the second substrate 20 into contact with the top side 12 of the first substrate 10. The second substrate 20 can be bonded to the first substrate 10 by the application of pressure, heat, electrostatic force, or combinations thereof.

FIG. 1D schematically illustrates an alternative embodiment to the bonding system 100 of FIGS. 1A to 1C. In the bonding system 100A of FIG. 1D, the rotation system 150 is replaced by rotation system 150A. In the rotation system 150A, the motor 152 and rotation arm 154 are not moved in the Z direction. In some embodiments, the actuator 156 may be omitted. Additionally, the sidewall 114 of the processing chamber 110 may be configured to hinder movement of the motor 152 and rotation arm 154 in the Z direction, and the seal assembly 122 may be replaced by a rotation seal 124 that is configured to seal against the rotation arm 154 accordingly.

The second chuck 140 is shown in the position as depicted in FIG. 1B, namely having been rotated about an axis in the X direction, such that the top side 22 of the second substrate 20 faces the top side 12 of the first substrate 10. The first chuck 130 with the first substrate 10 is shown having been moved in the positive Z direction towards the second substrate 20 by an actuator 128. In some examples that may be combined with other examples, the actuator 128 includes a motor, such as a stepper motor, that rotates a lead screw. In some examples that may be combined with other examples, the actuator 128 includes a piston.

In some embodiments, the controller 170 controls the actuator 128 to move the first chuck 130 in the positive Z direction to move the first chuck 130 and the first substrate 10 towards the second substrate 20 within the processing volume 112. In some examples, the actuator moves the first chuck 130 until the top side 12 of the first substrate 10 contacts the top side 22 of the second substrate 20.

However, in other examples, the actuator moves the first chuck 130 until the top side 12 of the first substrate 10 is separated from the top side 22 of the second substrate 20 by a relatively small distance, such as 25 mm or less, 20 mm or less, 15 mm or less, 10 mm or less, or 5 mm or less. In at least some of such examples, one or more components of the first chuck 130 and/or one or more components of the second chuck 140 are actuated to bring the top side 22 of the second substrate 20 into contact with the top side 12 of the first substrate 10. The second substrate 20 can be bonded to the first substrate 10 by the application of pressure, heat, electrostatic force, or combinations thereof.

In some embodiments that may be combined with other embodiments, after the second substrate 20 has been bonded to the first substrate 10, the second substrate 20 is released from the second chuck 140. The first substrate 10 with the second substrate 20 bonded thereto remains chucked to the first chuck 130. Then, the second chuck 140 is moved by the actuator 156 in the positive Z direction away from the first chuck 130. Alternatively, or additionally, the first chuck is moved by the actuator 128 in the negative Z direction away from the second chuck 140. Then a robot arm (not shown) enters the processing chamber 110 via the access port 116, and removes the bonded substrates 10, 20.

In some embodiments that may be combined with other embodiments, after the second substrate 20 has been bonded to the first substrate 10, the first substrate 10 is released from the first chuck 130. The second substrate 20 with the first substrate 10 bonded thereto remains chucked to the second chuck 140. Then, the second chuck 140 is moved by the actuator 156 in the positive Z direction away from the first chuck 130. Alternatively, or additionally, the first chuck 130 is moved by the actuator 128 in the negative Z direction away from the second chuck 140. Then a robot arm (not shown) enters the processing chamber 110 via the access port 116, and removes the bonded substrates 10, 20. In some examples, the motor 152 rotates the rotation arm 154 about the axis in the X direction by 180 degrees before the robot arm (not shown) removes the bonded substrates 10, 20. In other examples, the rotation arm 154 is not rotated about the axis in the X direction, but instead, the chucking electrode 146 in the second chuck 140 is deactivated to release the bonded substrates 10, 20 directly onto the robot arm.

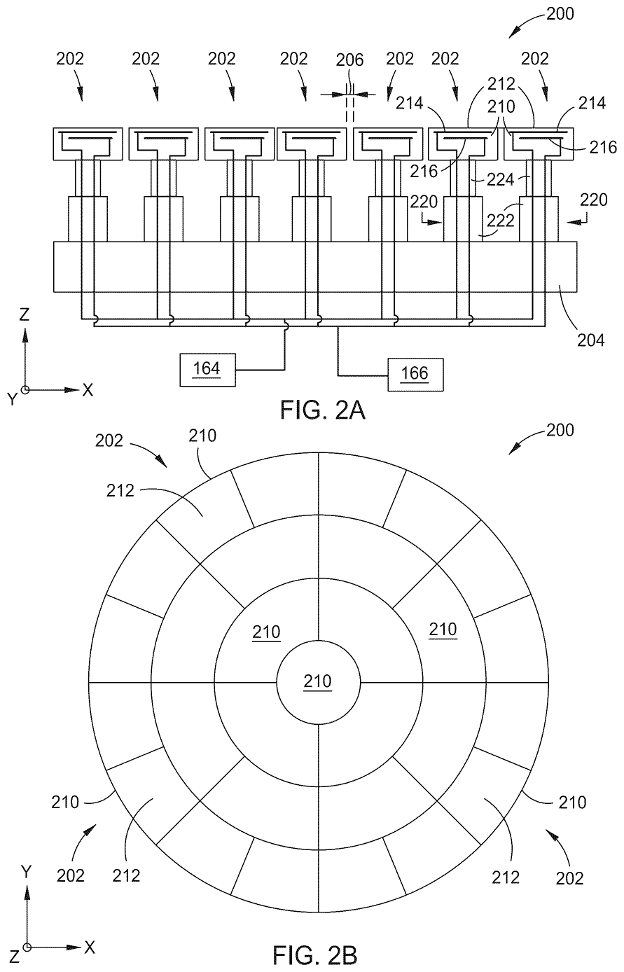

FIGS. 2A and 2B schematically illustrate a chuck 200. The chuck 200 may be used as the first chuck 130 and/or the second chuck 140. FIG. 2A is a cross-section in the X-Z plane; FIG. 2B is a plan view showing the X-Y plane.

The chuck 200 includes a plurality of chucking units 202. Each chucking unit 202 includes a chuck element 210. Each chuck element 210 includes a substrate support surface 212 that interfaces with a substrate (such as the first substrate 10 or the second substrate 20). When the chuck 200 is used as the first chuck 130, the plurality of substrate support surfaces 212 collectively forms the support surface 134 of the first chuck 130. When the chuck 200 is used as the second chuck 140, the plurality of substrate support surfaces 212 collectively forms the support surface 144 of the second chuck 140. As shown in FIG. 2A, each chuck element 210 includes one or more chucking electrodes 214 coupled to a voltage source 164. The voltage source 164 may represent the first voltage source 138 and/or the second voltage source 148. A portion of a substrate is chucked to the substrate support surface 212 of each chuck element 210 by the application of a voltage by the voltage source 164 to the one or more chucking electrodes 214 of each chuck element 210. In some embodiments that may be combined with other embodiments, the controller 170 manages the chucking of a substrate onto each substrate support surface 212 by controlling the application of a voltage by the voltage source 164 to the one or more chucking electrodes 214 of each chuck element 210. In some embodiments, each of the chucking units 202 include two or more electrodes 214 (not shown) that are each positioned in a lateral direction adjacent to the substrate supporting surface 212. In this configuration, the voltage source 164 is adapted to bias at least one of the two or more electrodes 214 relative to at least one of the other two or more electrodes 214 to electrostatically chuck the substrate to the substrate supporting surface 212.

In some embodiments that may be combined with other embodiments, each chuck element 210 includes one or more heaters 216 coupled to a power source 166. In some examples, the one or more heaters 216 are resistive heaters. In some embodiments that may be combined with other embodiments, the controller 170 manages the heating of a substrate disposed on the substrate support surfaces 212 by controlling the one or more heaters 216 of each chuck element 210.

Each chucking unit 202 is mounted to a base 204 of the chuck 200. As illustrated, in some embodiments that may be combined with other embodiments, all the chucking units 202 are mounted to a single base 204. Nevertheless, in some embodiments that may be combined with other embodiments, the base 204 may be segmented such that one or more first chucking units 202 are mounted to a first base segment of the chuck, and one or more second chucking units 202 are mounted to a second base segment of the chuck.

As illustrated, in some embodiments, adjacent chuck elements 210 are spaced apart by a gap 206. In some examples, the gap 206 is about 5 mm or less, such as 4.5 mm or less, 4 mm or less, 3.5 mm or less, 3 mm or less, 2.5 mm or less, or 2 mm or less. In other examples, the gap 206 is about 5 mm or more, such as 5.5 mm or more, 6 mm or more, 6.5 mm or more, or 7 mm or more.

In some embodiments that may be combined with other embodiments, the substrate support surface 212 of each chuck element 210 is planar. In some embodiments that may be combined with other embodiments, the substrate support surface 212 of each chuck element 210 includes a peripheral portion that is curved in the X-Z plane, the X-Y plane, and/or in the Y-Z plane. In some examples, the chuck elements 210 are shaped such that edges of adjacent chuck elements 210 do not rub or interact during various actuations of the chuck elements 210.

FIG. 2B schematically illustrates a plan view of the chuck 200 showing the X-Y plane. In some embodiments that may be combined with other embodiments, the chucking units 202 and corresponding chuck elements 210 are arranged in concentric arrays. In the illustrated example, a centrally-positioned chuck element 210 is surrounded by an array of four chuck elements 210 that is surrounded by an array of eight chuck elements 210. The array of eight chuck elements 210 is surrounded by an array of 16 chuck elements 210. Although the example shown in FIG. 2B includes 29 chuck elements 210, it is to be appreciated that in some embodiments, the chuck includes more than 29 chuck elements 210 or fewer than 29 chuck elements 210.

Returning to FIG. 2A, each chucking unit 202 includes a driver 220 that couples the corresponding chuck element 210 to the base 204. Each driver 220 is capable of moving the corresponding chuck element 210 independently of the other chuck elements 210. Each driver 220 moves the corresponding chuck element 210 at least partially along the Z direction. As explained in more detail below, each driver 220 includes a first actuator 222 and a second actuator 224. The first actuator 222 is coupled to the base 204 and to the second actuator 224. The second actuator 224 is coupled to the first actuator 222 and to the corresponding chuck element 210. The first actuator 222 moves the second actuator 224 and the corresponding chuck element 210 with respect to the base 204 (i.e. towards or away from the base 204). The second actuator 224 moves the corresponding chuck element 210 with respect to the first actuator 222 and with respect to the base 204 (i.e. towards or away from the first actuator 222 and the base 204).

In some embodiments that may be combined with other embodiments, each driver 220 is configured such that a corresponding chuck element 210 moves only along the Z direction with respect to the base 204. However, in some embodiments that may be combined with other embodiments, the driver 220 of at least one chucking unit 202 may include a joint (such as a ball joint) that facilitates a range of motion for the corresponding chuck element 210 in the X direction, in the Y direction, and in intermediate directions between the X direction and the Y direction.

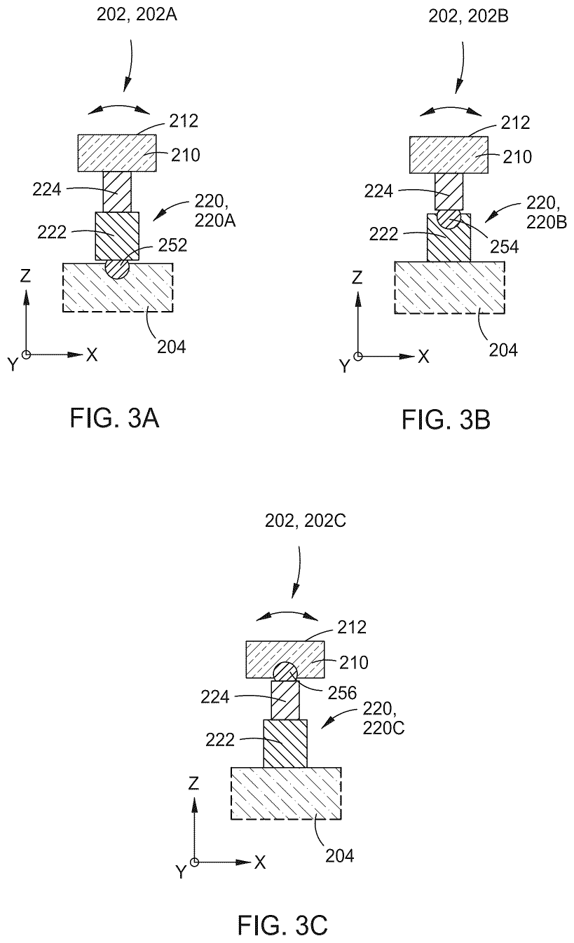

FIGS. 3A to 3C schematically illustrate embodiments of the chucking unit 202 in which the driver 220 includes a joint (such as a ball joint). In FIG. 3A, the chucking unit 202 is represented by chucking unit 202A, and the driver 220 is represented by driver 220A. The first actuator 222 is coupled to the base 204 by joint 252. The joint 252 is represented as a ball joint, although the joint 252 may be in the form of a gimbal, a universal joint, or any other coupling that facilitates a range of motion for the corresponding chuck element 210 in the X direction, in the Y direction, and in intermediate directions between the X direction and the Y direction. The first actuator 222, the second actuator 224, and the chuck element 210 can collectively pivot with respect to the base 204 about the joint 252 in the X direction, in the Y direction, and in intermediate directions between the X direction and the Y direction.

In FIG. 3B, the chucking unit 202 is represented by chucking unit 202B, and the driver 220 is represented by driver 220B. The first actuator 222 is coupled to the base 204 without the joint 252, and does not pivot with respect to the base 204. The second actuator 224 is coupled to the first actuator 222 by a joint 254. The joint 254 is represented as a ball joint, although the joint 254 may be in the form of a gimbal, a universal joint, or any other coupling that facilitates a range of motion for the corresponding chuck element 210 in the X direction, in the Y direction, and in intermediate directions between the X direction and the Y direction. The second actuator 224 and the chuck element 210 can collectively pivot with respect to the base 204 and the first actuator 222 about the joint 254 in the X direction, in the Y direction, and in intermediate directions between the X direction and the Y direction.

In FIG. 3C, the chucking unit 202 is represented by chucking unit 202C, and the driver 220 is represented by driver 220C. The first actuator 222 is coupled to the base 204 without the joint 252, and does not pivot with respect to the base 204. The second actuator 224 is coupled to the first actuator 222 without the joint 254, and does not pivot with respect to the base 204 or with respect to the first actuator 222. The chuck element 210 is coupled to the second actuator 224 by a joint 256. The joint 256 is represented as a ball joint, although the joint 256 may be in the form of a gimbal, a universal joint, or any other coupling that facilitates a range of motion for the corresponding chuck element 210 in the X direction, in the Y direction, and in intermediate directions between the X direction and the Y direction. The chuck element 210 alone can pivot with respect to the base 204, the first actuator 222, and the second actuator 224 about the joint 256 in the X direction, in the Y direction, and in intermediate directions between the X direction and the Y direction.

In some embodiments that may be combined with other embodiments, at least one chucking unit 202 of the chuck 200 may be configured as chucking unit 202A. In some embodiments that may be combined with other embodiments, at least one chucking unit 202 of the chuck 200 may be configured as chucking unit 202B. In some embodiments that may be combined with other embodiments, at least one chucking unit 202 of the chuck 200 may be configured as chucking unit 202C.

In some embodiments that may be combined with other embodiments, at least one driver 220 of a chucking unit 202 may be configured with more than one joint that facilitates a range of motion for the corresponding chuck element 210 in the X direction, in the Y direction, and in intermediate directions between the X direction and the Y direction. In some examples, the at least one driver 220 may be configured to include the joint 252 of driver 220A and the joint 254 of driver 220B. In some examples, the at least one driver 220 may be configured to include the joint 252 of driver 220A and the joint 256 of driver 220C. In some examples, the at least one driver 220 may be configured to include the joint 254 of driver 220B and the joint 256 of driver 220C. In some examples, the at least one driver 220 may be configured to include the joint 252 of driver 220A, the joint 254 of driver 220B, and the joint 256 of driver 220C.

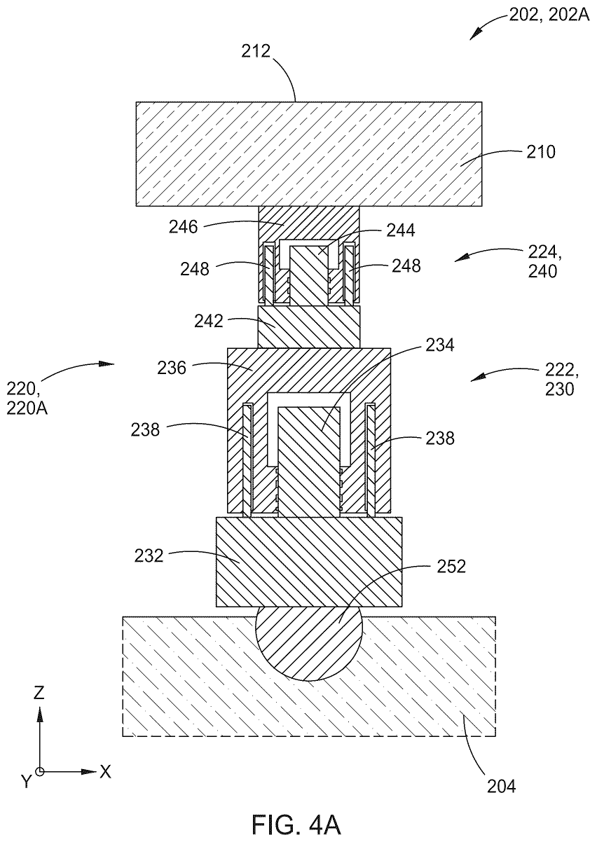

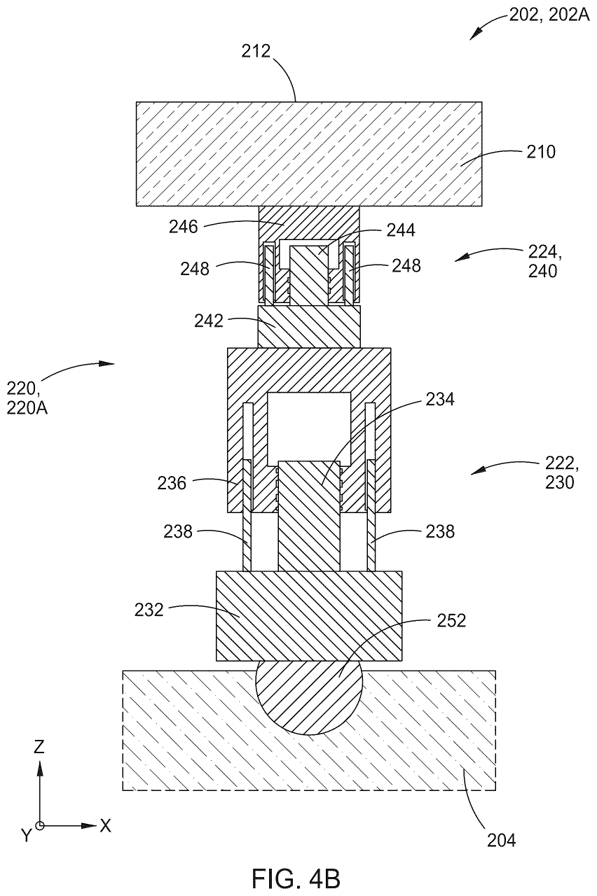

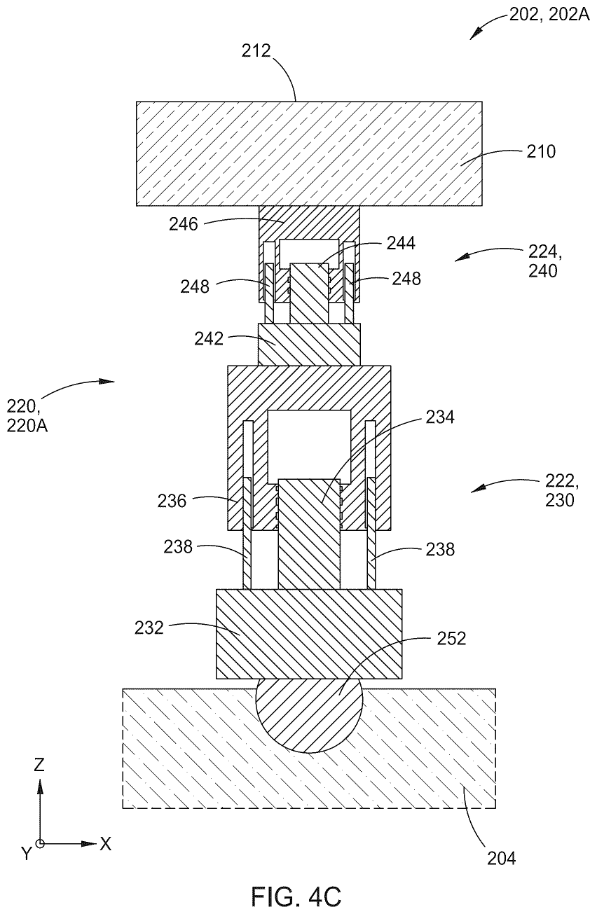

FIG. 4A schematically illustrates an example of the chucking unit 202 in further detail. The chucking unit 202 is represented by chucking unit 202A, and the driver 220 is represented by driver 220A. The first actuator 222 is represented by first actuator 230. The second actuator 224 is represented by second actuator 240. Although the Figure depicts the chucking unit 202A, it is to be understood that the exemplary aspects can pertain also to the chucking unit 202B, the chucking unit 202C, or the chucking unit 202 without any of the joints 252, 254, or 256.

The first actuator 230 is configured to move the chuck element 210 in first increments of distance. The second actuator 240 is configured to move the chuck element 210 in second increments of distance. In some embodiments, the second increments are of a different length than the first increments. In some embodiments, the second increments are shorter than the first increments. In some embodiments, the second increments are longer than the first increments.

In some embodiments that may be combined with other embodiments, the first actuator 230 and the second actuator 240 are configured to operate according to a common mode of operation. In some examples, both the first actuator 230 and the second actuator 240 include a same type of motive power, such as one of a solenoid, a direct current motor, an alternating current motor, a stepper motor, a linear motor, a hydraulic piston, an electrohydraulic actuator, pneumatic piston, piezoelectric actuator, or a magnetostrictive actuator.

In some embodiments that may be combined with other embodiments, the first actuator 230 and the second actuator 240 are configured to operate according to different modes of operation. In some examples, the first actuator 230 includes a different type of motive power to that of the second actuator 240. In some of such examples, the first actuator 230 includes one of a solenoid, a direct current motor, an alternating current motor, a stepper motor, a linear motor, a hydraulic piston, an electrohydraulic actuator, pneumatic piston, piezoelectric actuator, or a magnetostrictive actuator. The second actuator 240 includes a different one of a solenoid, a direct current motor, an alternating current motor, a stepper motor, a linear motor, a hydraulic piston, an electrohydraulic actuator, pneumatic piston, piezoelectric actuator, or a magnetostrictive actuator.

As described above, the first actuator 230 is coupled to the base 204 via the joint 252. In the illustrated example, the first actuator 230 includes a stepper motor 232 coupled to the joint 252. The stepper motor 232 is coupled to a shaft 234. The stepper motor 232 operates to move the shaft 234, such as by rotation or by linear actuation. In the illustrated example, the shaft 234 is configured to convert rotation of the shaft 234 into linear motion, such as by including a lead screw. A follower 236 is engaged with the shaft 234. In some examples, the follower 236 is engaged with the lead screw such that rotation of the shaft 234 and the lead screw causes the follower 236 to move longitudinally along the lead screw. In some embodiments that may be combined with other embodiments, the follower 236 is engaged also to one or more guides 238. The one or more guides 238 prevent rotation of the follower 236 as the shaft 234 rotates, such that the follower 236 moves and along the one or more guides 238 as the shaft 234 rotates.

The stepper motor 232 moves the shaft 234 in successive increments, such as in successive increments of rotation. In some examples, each successive increment of rotation is the same as a previous increment of rotation of the shaft 234 by the stepper motor 232. The follower 236 moves successively in the first increments of distance as the shaft 234 rotates. In some examples, each successive first increment of distance is the same as a previous first increment of distance.

In some embodiments that may be combined with other embodiments, the first increment of distance is a known value. In some embodiments that may be combined with other embodiments, the first increment of distance is in a range of 0.01 mm to 5 mm, such as 0.05 mm to 2 mm, 0.1 mm to 1 mm, or 0.1 mm to 0.5 mm.

In the illustrated example, the follower 236 is coupled to the second actuator 240. In some configurations, the follower 236 is attached directly to the second actuator 240. In some configurations, the second actuator 240 incorporates the follower 236. In some configurations, the follower 236 is attached indirectly to the second actuator 240. For example, in driver 220B, the follower 236 is attached to the second actuator 240 via the joint 254. Movement of the follower 236 causes movement of the second actuator 240.

In the illustrated example, the second actuator 240 includes a piezoelectric actuator 242 coupled to a shaft 244. The piezoelectric actuator 242 operates to move the shaft 244, such as by rotation or by linear actuation. In the illustrated example, the shaft 244 is configured to convert rotation of the shaft 244 into linear motion such as by including a lead screw. A follower 246 is engaged with the shaft 244. In some examples, the follower 246 is engaged with the lead screw such that rotation of the shaft 244 and the lead screw causes the follower 246 to move longitudinally along the lead screw. In some embodiments that may be combined with other embodiments, the follower 246 is engaged also to one or more guides 248. The one or more guides 248 prevent rotation of the follower 246 as the shaft 244 rotates, such that the follower 246 moves and along the one or more guides 248 as the shaft 244 rotates.

The piezoelectric actuator 242 moves the shaft 244 in successive increments, such as in successive increments of rotation. In some examples, each successive increment of rotation is the same as a previous increment of rotation of the shaft 244 by the piezoelectric actuator 242. The follower 246 moves successively in the second increments of distance as the shaft 244 rotates. In some examples, each successive second increment of distance is the same as a previous second increment of distance.

In some embodiments that may be combined with other embodiments, the second increment of distance is a known value. In some embodiments that may be combined with other embodiments, the second increment of distance is in a range of 25 nm to 200 μm, such as 50 nm to 150 μm, 100 nm to 100 μm, 500 nm to 100 μm, 1 μm to 100 μm, or 50 μm to 100 μm.

In the illustrated example, the follower 246 is coupled to the chuck element 210. In some configurations, the follower 246 is attached directly to the chuck element 210. In some configurations, the chuck element 210 incorporates the follower 246. In some configurations, the follower 246 is attached indirectly to the chuck element 210. For example, in driver 220C, the follower 246 is attached to the chuck element 210 via the joint 256. Movement of the follower 246 causes movement of the chuck element 210.

FIGS. 4B and 4C schematically illustrate the chucking unit 202 depicted in FIG. 4A at different stages of actuation. In some embodiments that may be combined with other embodiments, actuation of the driver 220 moves the chuck element 210 into or out of engagement with a portion of a substrate (such as a portion of the first substrate 10 or a portion of the second substrate 20). In some embodiments that may be combined with other embodiments, actuation of the driver 220 moves the chuck element 210 after the chuck element 210 has engaged a portion of a substrate, such as to distort a portion of a substrate (e.g. to correct or induce a bow to a portion of the substrate). In some embodiments that may be combined with other embodiments, the controller 170 controls the actuation of the driver 220.

FIG. 4B shows the chucking unit 202 during actuation of the first actuator 230. The stepper motor 232 moves the shaft 234, such as by rotation. Rotation of the shaft 234 causes the follower 236 to move along the shaft 234 and the one or more guides 238, such as via interaction between the follower 236 and a lead screw on the shaft 234. In so doing, the first actuator 230 moves the second actuator 240 and the chuck element 210. As illustrated, in some examples, the first actuator 230 is operated while the second actuator 240 remains inactive. Alternatively, in other examples, the first actuator 230 and the second actuator 240 are operated simultaneously.

FIG. 4C shows the chucking unit 202 during actuation of the second actuator 240. The piezoelectric actuator 242 moves the shaft 244, such as by rotation. Rotation of the shaft 244 causes the follower 246 to move along the shaft 244 and the one or more guides 248, such as via interaction between the follower 246 and a lead screw on the shaft 244. In so doing, the second actuator 240 moves the chuck element 210. As illustrated, in some examples, the second actuator 240 is operated while the first actuator 230 remains inactive. Alternatively, in other examples, the first actuator 230 and the second actuator 240 are operated simultaneously.

Retraction of the chuck element 210 towards the base 204 (or towards the stepper motor 232 of the first actuator 230) involves a reversal of the actuation of the first actuator 230 and/or the second actuator 240. In some embodiments that may be combined with other embodiments, the controller 170 controls the actuation of the driver 220 to retract the chuck element 210.

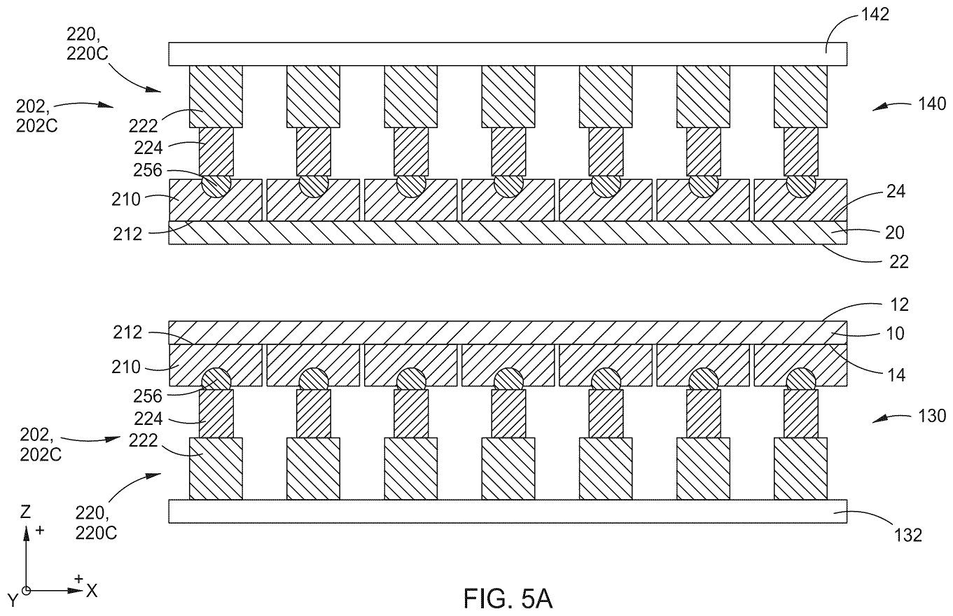

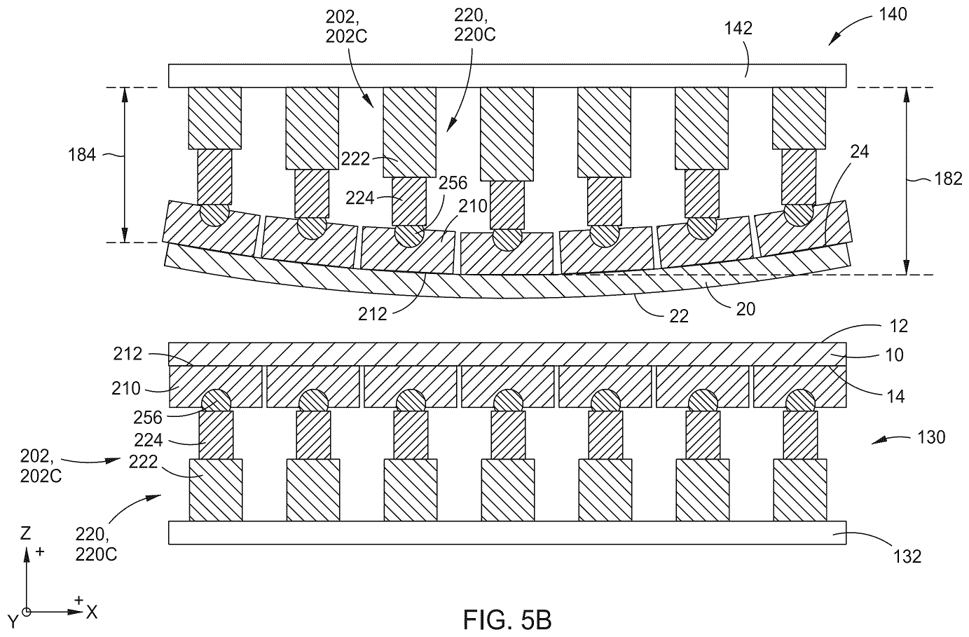

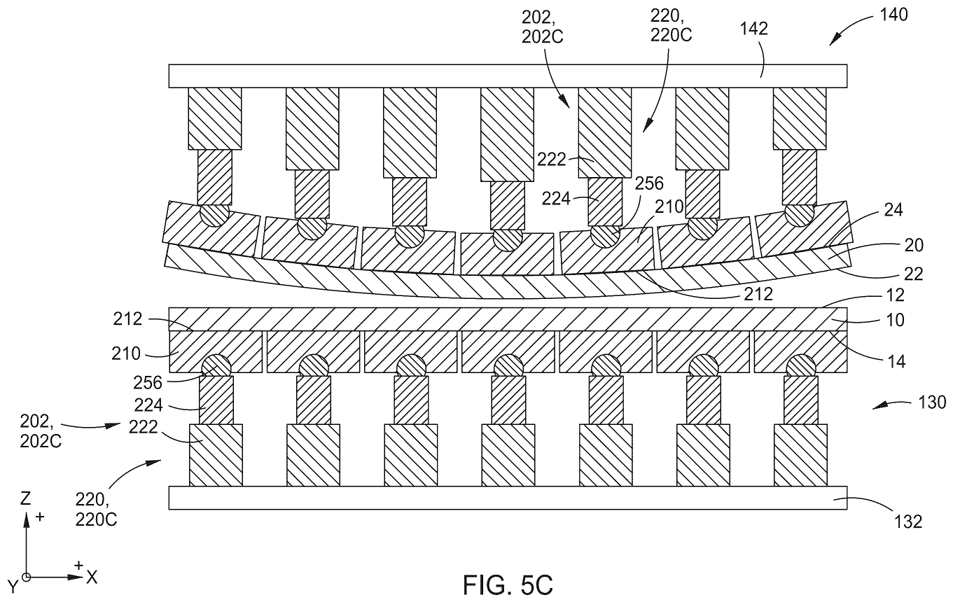

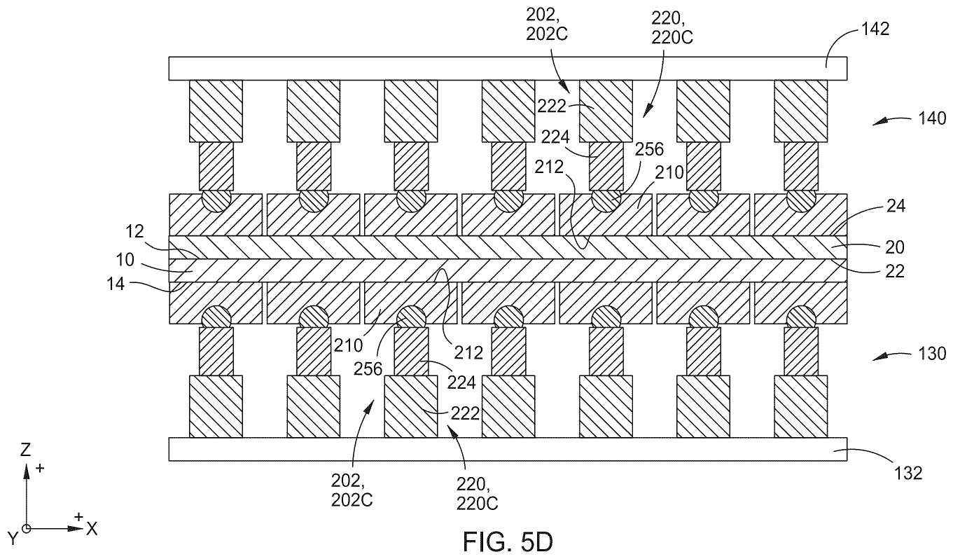

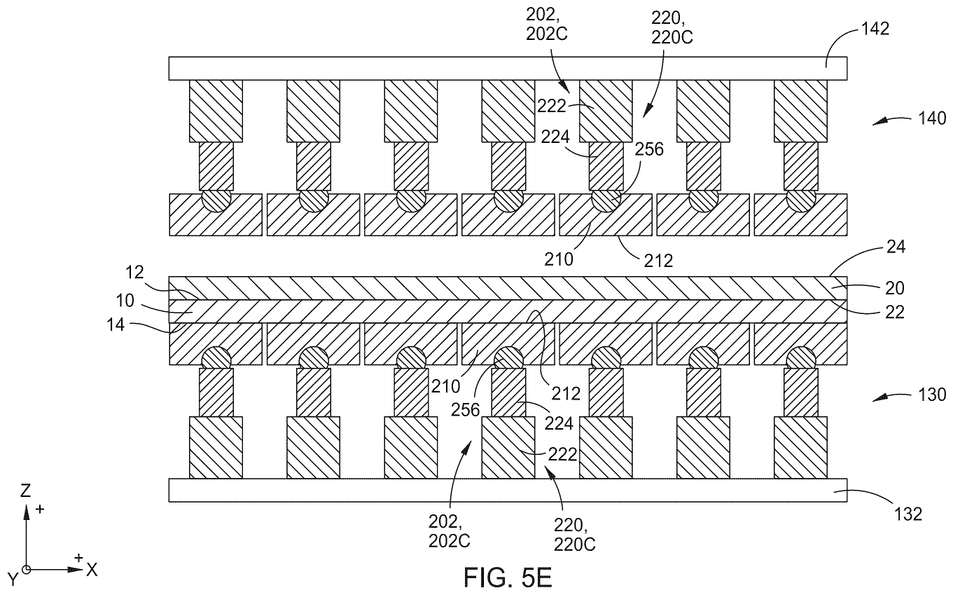

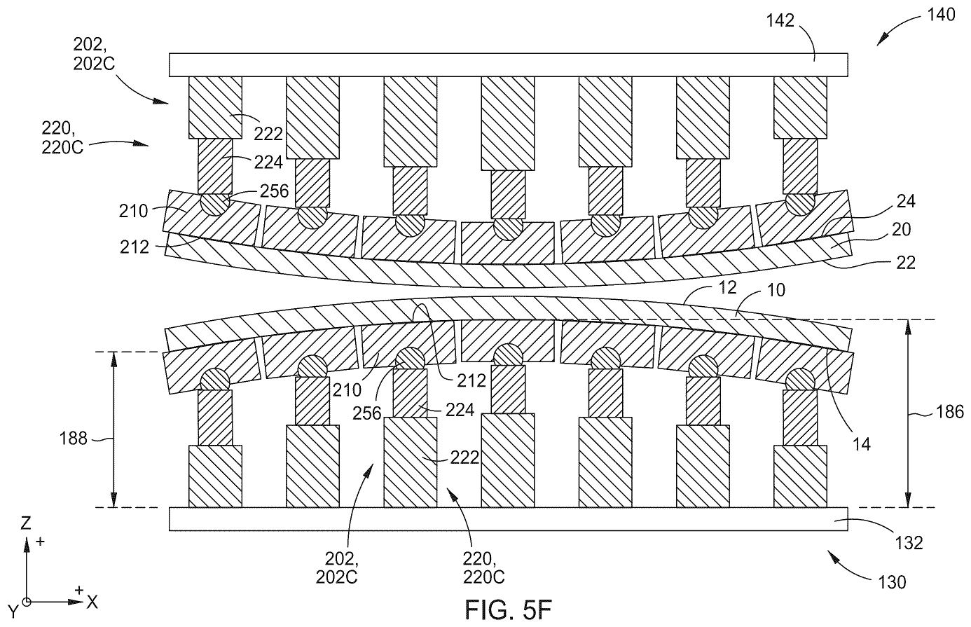

FIGS. 5A to 5F schematically illustrate substrate bonding operations in which the first chuck 130 and the second chuck 140 incorporate chucking units 202. Although the Figures depict each of the chucking units 202 to be configured as chucking unit 202C, it should be understood that any one or more of the chucking units 202 can be configured as chucking unit 202A, chucking unit 202B, chucking unit 202C, or the chucking unit 202 without any of the joints 252, 254, or 256. Furthermore, the driver 220 of any one or more of the chucking units 202 may be configured as a hybrid of any two or more of driver 220A, driver 220B, or driver 220C. As illustrated, in some embodiments that may be combined with other embodiments, all the chuck elements 210 of the first chuck 130 are coupled to corresponding drivers 220. Nevertheless, in some embodiments that may be combined with other embodiments, one or more of the chuck elements 210 of the first chuck 130 may not be coupled to corresponding drivers 220.

For clarity, components (such as components depicted in FIGS. 1A to 1D) auxiliary to the first chuck 130 and to the second chuck 140 have been omitted from the Figures. In some embodiments that may be combined with other embodiments, the controller 170 controls one or more of the operations depicted in FIGS. 5A to 5F.

In FIG. 5A, the first substrate 10 is chucked onto the substrate support surface 212 of each chuck element 210 of the first chuck 130, such as via actuation of each chucking electrode (214, FIG. 2A) using the first voltage source (138, FIGS. 1A-1D). In some embodiments that may be combined with other embodiments, a magnitude of the voltage applied to each chucking electrode 214 of each chuck element 210 of the first chuck 130 is the same. In some embodiments that may be combined with other embodiments, a magnitude of the voltage applied to the chucking electrode 214 of one chuck element 210 of the first chuck 130 is different from a magnitude of the voltage applied to the chucking electrode 214 of another chuck element 210 of the first chuck 130.

The second substrate 20 is chucked onto the substrate support surface 212 of each chuck element 210 of the second chuck 140, such as via actuation of each chucking electrode (214, FIG. 2A) using the second voltage source (148, FIGS. 1A-1D). In some embodiments that may be combined with other embodiments, a magnitude of the voltage applied to each chucking electrode 214 of each chuck element 210 of the second chuck 140 is the same. In some embodiments that may be combined with other embodiments, a magnitude of the voltage applied to the chucking electrode 214 of one chuck element 210 of the second chuck 140 is different from a magnitude of the voltage applied to the chucking electrode 214 of another chuck element 210 of the second chuck 140.

The top side 22 of the second substrate 20 is separated from the top side 12 of the first substrate 10 by a relatively small distance, such as 20 mm or less, 15 mm or less, or 10 mm or less.

In FIG. 5B, the second substrate 20 is deformed by the second chuck 140 to have a convex curvature. A distance 182 of a central portion of the bottom side 24 of the second substrate 20 from the base 142 of the second chuck 140 is greater than a distance 184 of a peripheral portion of the bottom side 24 of the second substrate 20 from the base 142 of the second chuck 140. In some examples, a difference between the distance 182 and the distance 184 is in a range of about 0.2 to 2.0 mm, such as from 0.2 mm to 1.5 mm, from 0.2 mm to 1.0 mm, or from 0.4 mm to 0.8 mm. As illustrated, in some embodiments that may be combined with other embodiments, the first substrate 10 is not deformed to have a convex curvature.

The second substrate 20 is deformed by actuating one or more of the drivers 220 of the second chuck 140 such that the corresponding chuck elements 210 distort one or more portions of the second substrate 20. As illustrated, the drivers 220 in a central portion of the second chuck 140 are actuated to a greater extension that the drivers 220 in a peripheral portion of the second chuck 140. In some embodiments that may be combined with other embodiments, a desired convex shape of the second substrate 20 is provided to the controller 170, and the controller 170 controls the actuation of each driver 220 of the second chuck 140 accordingly. In some embodiments that may be combined with other embodiments, one or more desired convex dimensions of the second substrate 20 are provided to the controller 170, and the controller 170 controls the actuation of each driver 220 of the second chuck 140 accordingly.

In some embodiments that may be combined with other embodiments, at least one of the chuck elements 210 of the second chuck 140 pivots about a corresponding joint (such as joint 252, 254, or 256—as illustrated) as the second substrate 20 deforms. Pivoting of each chuck element 210 promotes the maintenance of contact between the substrate support surface 212 of each chuck element 210 and the bottom side 24 of the second substrate 20. Furthermore, such contact facilitates the maintenance of the chucking force applied by each corresponding chucking electrode 214 to each portion of the second substrate 20. In some examples that may be combined with other examples, a chuck element 210 of the second chuck 140 pivots about a corresponding joint such that the substrate support surface 212 of the chuck element 210 is oriented tangentially to a bow of the second substrate 20 at the chuck element 210.

Nevertheless, in some embodiments that may be combined with other embodiments, at least one of the chuck elements 210 of the second chuck 140 does not pivot about a corresponding joint as the second substrate 20 deforms. In some examples, the chuck element 210 at the center of the second chuck 140 does not pivot about a corresponding joint as the second substrate 20 deforms.

In some embodiments that may be combined with other embodiments, the voltage applied to one or more chucking electrodes 214 is varied before, during, or after actuation of the drivers 220 to deform the second substrate 20. In some examples, the voltage applied to one or more chucking electrodes 214 is reduced to avoid unwanted attraction of the first substrate 10. In other examples, the voltage applied to one or more chucking electrodes 214 is increased to offset a reaction force of the second substrate 20 that tends to separate the second substrate 20 from the corresponding chuck element 210. In some embodiments that may be combined with other embodiments, the controller 170 controls the varying of the voltage applied to one or more chucking electrodes 214.

As illustrated, in some embodiments that may be combined with other embodiments, the first substrate 10 is not deformed to have a convex curvature.

In FIG. 5C, the second substrate 20 is positioned to make an initial contact with the top side 12 of the first substrate 10. In some embodiments that may be combined with other embodiments, the positioning of the second substrate 20 to make the initial contact with the top side 12 of the first substrate 10 is performed using the drivers 220 of the second chuck 140. In some embodiments that may be combined with other embodiments, the positioning of the second substrate 20 to make the initial contact with the top side 12 of the first substrate 10 is performed using the drivers 220 of the first chuck 130. In some embodiments that may be combined with other embodiments, the positioning of the second substrate 20 to make the initial contact with the top side 12 of the first substrate 10 is performed using the actuator (156, FIGS. 1A to 1C) of the rotation system (150, FIGS. 1A to 1C). In some embodiments that may be combined with other embodiments, the positioning of the second substrate 20 to make the initial contact with the top side 12 of the first substrate 10 is performed using the actuator (128, FIG. 1D) coupled to the first chuck 130. In some embodiments that may be combined with other embodiments, the controller 170 controls the positioning of the second substrate 20 to make the initial contact with the top side 12 of the first substrate 10.

A central portion of the top side 22 of the second substrate 20 contacts the top side 12 of the first substrate 10. A peripheral portion of the top side 22 of the second substrate 20 is not in contact with the top side 12 of the first substrate 10.

In FIG. 5D, the top side 22 of the second substrate 20 is bonded to the top side 12 of the first substrate 10. After the central portion of the top side 22 of the second substrate 20 contacts the top side 12 of the first substrate 10, the peripheral portion of the top side 22 of the second substrate 20 is moved into contact with the top side 12 of the first substrate 10. In some embodiments that may be combined with other embodiments, moving the peripheral portion of the top side 22 of the second substrate 20 into contact with the top side 12 of the first substrate 10 is performed by actuating successive drivers 220 of the second chuck 140 located between the central portion and the peripheral portion of the top side 22 of the second substrate 20.

In some embodiments that may be combined with other embodiments, moving the peripheral portion of the top side 22 of the second substrate 20 into contact with the top side 12 of the first substrate 10 is performed by reducing a voltage applied to successive chucking electrodes (214, FIG. 2A) of the chuck elements 210 of the second chuck 140 between the central and the peripheral portions of the top side 22 of the second substrate 20. In some embodiments that may be combined with other embodiments, the controller 170 controls the moving of the peripheral portion of the top side 22 of the second substrate 20 into contact with the top side 12 of the first substrate 10.

The first substrate 10 is bonded to the second substrate 20 by, for example, the application of pressure, heat, electrostatic force, or combinations thereof. In some embodiments that may be combined with other embodiments, the application of pressure, heat, or electrostatic force is performed using the first chuck 130 and/or the second chuck 140. In some embodiments that may be combined with other embodiments, the controller 170 controls the bonding of the first substrate 10 to the second substrate 20.

In FIG. 5E, the second ESC 140 is separated from the bonded first and second substrates 10, 20. The application of voltage to the chucking electrodes 214 of each chuck element 210 of the second chuck 140 is ceased, such as by the controller 170. In some embodiments that may be combined with other embodiments, separating the second chuck 140 from the second substrate 20 is performed by retracting the drivers 220 of the second chuck 140. In some embodiments that may be combined with other embodiments, separating the second chuck 140 from the second substrate 20 is performed by retracting the drivers 220 of the first chuck 130. In some embodiments that may be combined with other embodiments, separating the second chuck 140 from the second substrate 20 is performed using the actuator (156, FIGS. 1A to 1C) of the rotation system (150, FIGS. 1A to 1C). In some embodiments that may be combined with other embodiments, separating the second chuck 140 from the second substrate 20 is performed using the actuator (128, FIG. 1D) coupled to the first chuck 130. In some embodiments that may be combined with other embodiments, the controller 170 controls the separating of the second chuck 140 from the second substrate 20.

It is contemplated that instead of deforming the second substrate 20 into a convex curvature as shown in FIG. 5B, the first substrate 10 may be deformed by the first chuck 130 into a convex curvature while the second substrate 20 is not deformed into a convex curvature. In such embodiments, one or more of the actions of the bonding process described above may be performed by the corresponding drivers 220 or chuck elements 210 of the first chuck 130 instead of the drivers 220 or chuck elements 210 of the second chuck 140. Additionally, in some of such embodiments, the second chuck 140 does not incorporate chuck elements 210 that are actuated by corresponding drivers 220.

FIG. 5F schematically illustrates a pre-bonding configuration, similar to that depicted in FIG. 5B, in which the second substrate 20 is deformed to have a convex curvature (such as shown in FIG. 5B), and the first substrate 10 is deformed also to have a convex curvature opposite the convex curvature of the second substrate 20. In such embodiments, one or more of the actions of the bonding process described above may be performed by the corresponding drivers 220 or chuck elements 210 of the first chuck 130 with respect to the first substrate 10.

A distance 186 of a central portion of the bottom side 14 of the first substrate 10 from the base 132 of the first chuck 130 is greater than a distance 188 of a peripheral portion of the bottom side 14 of the first substrate 10 from the base 132 of the first chuck 130. In some examples, a difference between the distance 186 and the distance 188 is in a range of about 0.2 to 2.0 mm, such as from 0.2 mm to 1.5 mm, from 0.2 mm to 1.0 mm, or from 0.4 mm to 0.8 mm.

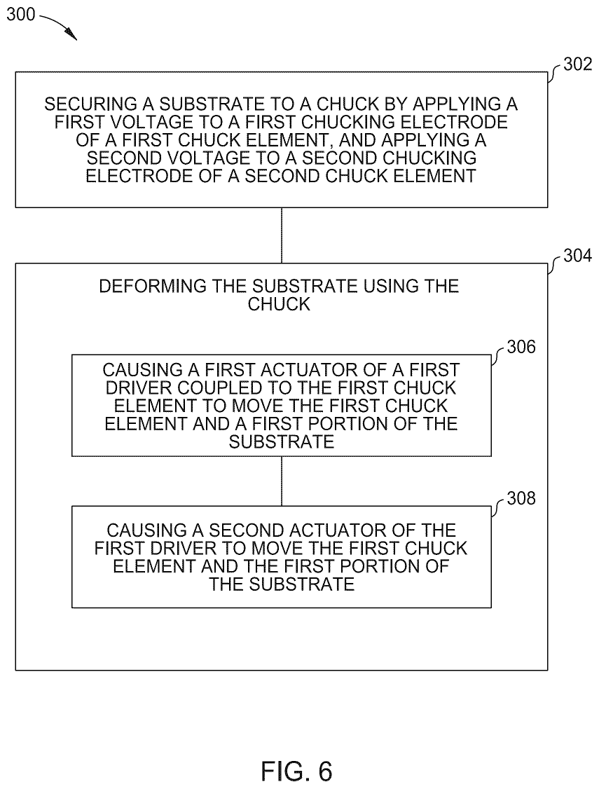

FIG. 6 is a flowchart of a method 300 of manipulating a substrate, such as the first substrate 10 or the second substrate 20. In some embodiments that may be combined with other embodiments, the method is performed by a chuck configured as chuck. In some examples that may be combined with other examples, the chuck is operated as the first chuck. In some examples that may be combined with other examples, the chuck is operated as the second chuck.

Operation 302 includes securing a substrate to a chuck by applying a first voltage to a first chucking electrode of a first chuck element, and applying a second voltage to a second chucking electrode of a second chuck element. In some embodiments that may be combined with other embodiments, the first chuck element or the second chuck element are configured as chuck element 210.

Operation 304 includes deforming the substrate using the chuck. In some embodiments that may be combined with other embodiments, operation 304 includes operation 306, which includes causing a first actuator of a first driver coupled to the first chuck element to move the first chuck element and a first portion of the substrate. In some embodiments that may be combined with other embodiments, the first driver is configured as driver 220 (i.e., without a joint that facilitates a range of motion for the corresponding chuck element 210 in the X direction, in the Y direction, and in intermediate directions between the X direction and the Y direction), or as driver 220A, driver 220B, or driver 220C. In some embodiments that may be combined with other embodiments, the first driver is configured as a hybrid of any two or more of driver 220A, driver 220B, or driver 220C. In some embodiments that may be combined with other embodiments, the first actuator of the first driver is configured as first actuator 222 or first actuator 230.

In some embodiments that may be combined with other embodiments, operation 304 includes operation 308, which includes causing a second actuator of the first driver to move the first chuck element and the first portion of the substrate. In some embodiments that may be combined with other embodiments, the second actuator of the first driver is configured as second actuator 224 or second actuator 240.

In some embodiments that may be combined with other embodiments, the first actuator moves the first chuck element and the first portion of the substrate in first increments of distance. In some embodiments that may be combined with other embodiments, the second actuator moves the first chuck element and the first portion of the substrate in second increments of distance. In some embodiments that may be combined with other embodiments, the second increments are different from the first increments. In some examples, the second increments are shorter than the first increments. In some examples, the second increments are longer than the first increments.

In some embodiments that may be combined with other embodiments, the second actuator of the first driver is inactive while moving the first chuck element and the first portion of the substrate using the first actuator of the first driver. In some embodiments that may be combined with other embodiments, the first actuator of the first driver is inactive while moving the first chuck element and the first portion of the substrate using the second actuator of the first driver.

In some embodiments that may be combined with other embodiments, the method 300 includes causing a first actuator of a second driver coupled to the second chuck element to move the second chuck element and a second portion of the substrate. In some embodiments that may be combined with other embodiments, the second driver is configured as driver 220 (i.e., without a joint that facilitates a range of motion for the corresponding chuck element 210 in the X direction, in the Y direction, and in intermediate directions between the X direction and the Y direction), or as driver 220A, driver 220B, or driver 220C. In some embodiments that may be combined with other embodiments, the second driver is configured as a hybrid of any two or more of driver 220A, driver 220B, or driver 220C. In some embodiments that may be combined with other embodiments, the first actuator of the second driver is configured as first actuator 222 or first actuator 230.

In some embodiments that may be combined with other embodiments, the method 300 includes causing a second actuator of the second driver to move the second chuck element and the second portion of the substrate. In some embodiments that may be combined with other embodiments, the second actuator of the second driver is configured as second actuator 224 or second actuator 240.

In some embodiments that may be combined with other embodiments, the first driver moves the first chuck element and the first portion of the substrate by a first distance with respect to a base of the chuck. In some embodiments that may be combined with other embodiments, the second driver moves the second chuck element and the second portion of the substrate by a second distance with respect to a base of the chuck. In some examples, the second distance is the same as the first distance. In some examples, the second distance is different from the first distance. In some examples, the actions of the first and second drivers deform the substrate into a convex shape. In some embodiments that may be combined with other embodiments, at least one of the first or second chuck elements pivots about a corresponding joint (such as joint 252, 254, or 256) while the substrate deforms.

The method 300 may be performed using any of the systems and apparatus disclosed herein. The method 300 may include any of the actions, activities, or processes disclosed herein. In some embodiments that may be combined with other embodiments, the method 300 is performed under a vacuum pressure. In some embodiments that may be combined with other embodiments, the method 300 includes bonding the substrate to a second substrate, such as described above. In some examples that may be combined with other examples, bonding the substrate to a second substrate is performed under vacuum.

Systems, apparatus, and methods of the present disclosure facilitate the bonding of one substrate to another substrate. At least one substrate can be deformed to enable precise control of an initial contact location and extent between the substrate and the other substrate. The systems, apparatus, and methods of the present disclosure further enable precise control of the progression of substrate-to-substrate contact during the bonding process.

It is contemplated that any one or more elements or features of any one disclosed embodiment or example may be beneficially incorporated in any one or more other non-mutually exclusive embodiments or examples. While the foregoing is directed to embodiments of the present disclosure, other and further embodiments of the disclosure may be devised without departing from the basic scope thereof, and the scope thereof is determined by the claims that follow.

What is claimed is:

1. An apparatus for chucking a substrate, the apparatus comprising:
a chuck element including a chucking electrode and a substrate support surface;
a first actuator coupled to the chuck element, and configured to move the chuck element in first increments of distance; and
a second actuator coupled to the chuck element, and configured to move the chuck element in second increments of distance, the second increments different from the first increments.

2. The apparatus of claim 1, wherein:
the second actuator is coupled between the chuck element and the first actuator; and
the first actuator is configured to move the second actuator and the chuck element in the first increments of distance.

3. The apparatus of claim 2, further comprising a joint coupled to one of the first or second actuators, the joint configured to permit the chuck element to pivot with respect to the corresponding first or second actuator.

4. The apparatus of claim 3, wherein the joint is coupled between the chuck element and the second actuator.

5. The apparatus of claim 1, wherein:
the first actuator is configured to operate according to a first mode of operation; and
the second actuator is configured to operate according to a second mode of operation different from the first mode of operation.

6. The apparatus of claim 5, wherein:
the first actuator includes a first shaft coupled to a motor; and
upon actuation:
the motor moves the first shaft; and
a first follower moves along the first shaft.

7. The apparatus of claim 6, wherein:
the first shaft includes a lead screw; and
the first follower is engaged with the lead screw such that rotation of the first shaft and the lead screw by the motor causes the first follower to move longitudinally along the lead screw.

8. The measurement probe of claim 6, wherein:
the second actuator is coupled to the first follower;
the second actuator includes a second shaft coupled to a piezoelectric actuator; and
upon actuation:
the piezoelectric actuator moves the second shaft; and
a second follower coupled to the chuck element moves along the second shaft.

9. The apparatus of claim 8, wherein:
the second shaft includes a lead screw; and
the second follower is engaged with the lead screw such that rotation of the second shaft and the lead screw by the piezoelectric actuator causes the second follower to move longitudinally along the lead screw.

10. A chuck for a substrate, the chuck comprising:
a base; and
a plurality of chucking units coupled to the base, wherein each chucking unit includes:
a chuck element comprising a chucking electrode and a substrate support surface; and
a driver coupling the chuck element to the base, the driver comprising:
a first actuator configured to move the chuck element relative to the base in first increments of distance; and
a second actuator configured to move the chuck element relative to the base in second increments of distance, the second increments different from the first increments.

11. The chuck of claim 10, wherein:
the second actuator is coupled between the chuck element and the first actuator; and
the first actuator is configured to move the second actuator relative to the base in the first increments of distance.

12. The chuck of claim 11, wherein the driver further comprises a joint coupled to one of the first or second actuators, the joint configured to permit the chuck element to pivot with respect to the corresponding first or second actuator.

13. The chuck of claim 12, wherein the joint is coupled between the chuck element and the second actuator.

14. The chuck of claim 10, wherein:
the first actuator is configured to operate according to a first mode of operation; and
the second actuator is configured to operate according to a second mode of operation different from the first mode of operation.

15. A method of manipulating a substrate, comprising:
securing a substrate to a chuck by applying a first voltage to a first chucking electrode of a first chuck element, and applying a second voltage to a second chucking electrode of a second chuck element; and
deforming the substrate using the chuck by:
causing a first actuator of a first driver coupled to the first chuck element to move the first chuck element and a first portion of the substrate; and
causing a second actuator of the first driver to move the first chuck element and the first portion of the substrate.

16. The method of claim 15, wherein:
the first actuator moves the first chuck element and the first portion of the substrate in first increments of distance; and
the second actuator moves the first chuck element and the first portion of the substrate in second increments of distance, the second increments different from the first increments.

17. The method of claim 15, wherein the first actuator of the first driver is inactive while moving the first chuck element and the first portion of the substrate using the second actuator of the first driver.

18. The method of claim 15, wherein deforming the substrate using the chuck further comprises:
causing a first actuator of a second driver coupled to the second chuck element to move the second chuck element and a second portion of the substrate; and
causing a second actuator of the second driver to move the second chuck element and the second portion of the substrate.

19. The method of claim 18, wherein:
the first driver moves the first chuck element and the first portion of the substrate by a first distance; and
the second driver moves the second chuck element and the second portion of the substrate by a second distance different from the first distance, thereby deforming the substrate into a convex shape.

20. The method of claim 15, wherein at least one of the first or second chuck elements pivots about a corresponding joint while the substrate deforms.
